(19) United States
(12) Patent Application Publication
(10) Pub. No.: US 2025/0253125 A1
(43) Pub. Date: Aug. 7, 2025

(54) SYSTEM AND METHOD FOR MANAGING SOLID PHASE PRECURSORS FOR AN ION IMPLANTATION SYSTEM

(71) Applicant: Axcelis Technologies, Inc., Beverly, MA (US)

(72) Inventors: Neil J. Bassom, Hamilton, MA (US); Neil Colvin, Merrimack, NH (US); Vladimir Romanov, Danville, NH (US); Vincent Szeto, Newton, MA (US)

(21) Appl. No.: 18/981,858

(22) Filed: Dec. 16, 2024

Related U.S. Application Data
(60) Provisional application No. 63/550,706, filed on Feb. 7, 2024.

(51) Int. Cl. H01J 37/30; H01J 37/317

(52) U.S. Cl. CPC H01J 37/3007; H01J 37/3171; H01J 2237/006; H01J 2237/057; H01J 2237/303

(57) ABSTRACT

A filter is configured to impede a flow of vapor from a vaporizer to an arc chamber in an ion implantation system. The flow is impeded to such a degree that the vaporizer must be operated at a higher temperature to match the flow rate that would result without the filter. Increasing the vaporizer temperature at which the vaporizer supplies the arc chamber with an operative flow rate of a vapor of an ion source material contained in the vaporizer prevents entry to the arc chamber of ion source material that is inadvertently vaporized by waste heat from the arc chamber while another species is being implanted. The filter may have a temperature-dependent permeability so as to provide a sharp transition between a temperature range at which the vapor flow is effectively cut off and a temperature range at which the vapor flow is at an operative rate.

### REFERENCE TO RELATED APPLICATIONS

This application claims the benefit of U.S. Provisional Application Ser. No. 63/550,706 filed Feb. 7, 2024, entitled, “SYSTEM AND METHOD FOR MANAGING SOLID PHASE PRECURSORS FOR AN ION IMPLANTATION SYSTEM”, the contents of which are herein incorporated by reference in their entirety.

### BACKGROUND

Ion implantation systems are essential tools in the integrated circuit device manufacturing industry. In an ion implantation system, ions of a specific element are accelerated and directed into a substrate to change its properties. The effectiveness of an ion implantation is dependent on the quality and consistency of the ion source material. Gases are often the first choice for ion source materials because the flow rates of gases into an arc chamber of an ion implantation system can be controlled easily. For some ions, however, solid phase precursors are selected because a suitable gaseous precursor is not available or for some other reason. The solid phase precursor is placed in a vaporizer that is connected to the arc chamber by an open passage. The vaporizer heats the solid phase precursor to induce sublimation and provide a flow of vapor. The vapor forms in the vaporizer and travels through the open passage to supply the arc chamber. A plurality of vaporizers may be connected to an arc chamber to allow rapid switching between precursors.

### BRIEF DESCRIPTION OF THE DRAWINGS

FIGS. 1A-1B are two plots showing how the flow of material from a vaporizer into an ion source is affected by a change in vaporizer setpoint temperature when using a filter according to some embodiments of the present disclosure.

FIG. 2 illustrates an ion source with a filter in accordance with some embodiments.

FIG. 3 illustrates an ion source with a filter according to some other embodiments.

FIG. 4 illustrates a filter according to some embodiments.

FIG. 5 illustrates a canister in accordance with some aspects of the present disclosure.

FIG. 6 illustrates an ion source using the canister of FIG. 5.

FIG. 7 illustrates an ion source with a canister according to another embodiment.

FIG. 8 illustrates an ion implantation system in accordance with some aspects of the present disclosure.

FIG. 9 provides a flow chart for a method illustrating several aspect of the present disclosure.

### DETAILED DESCRIPTION

The present disclosure provides many different embodiments, or examples, for implementing different features of this disclosure. Specific components and arrangements are provided to clarify and exemplify the disclosure. These specific examples should not be interpreted as limiting the scope of what is claimed.

Aluminum (Al) is highly desirable for doping silicon carbide (SiC) substrates used in making high voltage devices. Aluminum ions are among those for which a suitable gaseous precursor is not available. Instead, an aluminum salt such as aluminum chloride (AlCl₃), aluminum iodide (AlI₃), or the like is typically used. In comparison with other solid phase precursors that are commonly used in ion implantation systems, aluminum salts are exceptionally volatile.

The vaporizer is often held within an ion source within a terminal of an ion implantation system. The ion source is an enclosed structure that includes the arc chamber, and it is desirable for the vaporizer to be within that enclosed structure so that the vaporizer and the arc chamber are separated by only a short passage. It has been found that waste heat from the arc chamber can heat the vaporizer to temperatures at which aluminum salts vaporize at significant rates even while the vaporizer is offline, and while another species is being implanted. Although a mass analyzer will separate ion species and select only the desired species for the ion beam, the inadvertently vaporized aluminum salt may reach such concentrations in the arc chamber as to significantly reduce a rate at which ions of the desired species are generated and to cause a reduction in beam current. An autotune feature may increase the arc chamber power in an attempt to raise the beam current to a target value. The increased arc chamber power in turn results in more waste heat, which increases the aluminum salt vaporization rate. The increase in aluminum salt vaporization rate may defeat the attempt to increase the beam current.

The present disclosure solves this problem by impeding a flow of vapor from the vaporizer to the arc chamber. The flow is impeded with a structure comprising a sheet or plug of material, referred to herein by the term “filter”. The filter restricts the flow to such a degree that the vaporizer must be operated at a much higher temperature to match the flow rate that would result without the filter. In some embodiments, the filter is disc-shaped.

A vaporizer comprises an oven and a heater. In some embodiments, a thermocouple is configured to track the oven temperature and a controller operates the heater to drive the measured temperature to a setpoint. The filter provides an impediment to flow such that the setpoint temperature at which a given flow rate of material from the vaporizer to the arc chamber is achieved is increased. In some embodiments, the setpoint temperature is increased by at least about 20° C. In some embodiments, the setpoint temperature is increased by at least about 30° C. In some embodiments, the setpoint temperature is increased by at least about 50° C. The effect of the filter is as if the sublimation temperature of the ion source material were increased to a point where vaporization of the source material by waste heat ceased to be a concern.

The impediment to flow may also be characterized in terms of a partial pressure differential at which a given flow rate of the ion source material from the vaporizer to the arc chamber is achieved. In some embodiments, the filter increases the partial pressure differential at which a given flow rate is achieved by at least a factor or 2, which means that the filter is the primary impediment to flow. In some embodiments, the filter increases the partial pressure differential at which a given flow rate is achieved by at least a factor or 10.

The filter may be in any suitable location where it is effective for impeding the flow of a vapor of the ion source material formed in the oven to the arc chamber. In some embodiments, the filter is at the top of the oven. The ion source material may be placed in the oven, the filter placed over the oven, and the filter clamped in place. In some embodiments, the filter is in the passage that connects the vaporizer to the arc chamber. In some embodiments, the filter is inside the oven.

Some aspects of the invention relate to a canister that contains the ion source material and to which the filter is attached. The oven is typically provided with a crucible. In some embodiments, the canister replaces the crucible. In some other embodiments, the canister fits inside the crucible. The canister comprises a container body into which the ion source material is placed. The filter may be clamped between the container body and a lid for the container body. The lid may have an orifice through which vaporized ion source material flows after having passed through the filter. In some embodiments, the ion source material is shipped and stored in the canister. This arrangement is particularly convenient for ion source materials that are hygroscopic, hazardous, or otherwise difficult to handle. The canister with the ion source material may be placed in the oven without otherwise handling the ion source material. The ion implantation system may then be operated as with ion source material placed directly in the crucible except that the setpoint temperature is adjusted upward to overcome the impediment to flow that is provided by the filter.

In some embodiments, filter comprises a porous structure. In some embodiments, the porous structure is a frit. The porosity and thickness of the porous structure may be selected to provide the desired flow impedance. One difficulty with using a porous structure is that the ion source material may deposit within the porous structure. This disadvantage may be turned into an advantage by providing a second heater that directly heats the filter. When the oven heater and the second heater are turned off, the ion source material deposits on the filter, reducing its permeability and improving the isolation of the ion source material from the arc chamber. The permeability may subsequently be restored by heating the filter.

In some embodiments, the filter comprises a membrane. In some embodiments, the filter membrane is non-porous. The membrane may be a polymer such as Teflon™ or the like. In some embodiments, a mesh supports the membrane. The vaporized ion source material passes through the membrane by absorbing into the membrane on a high pressure side, diffusing through the membrane, and desorbing from the membrane on a low pressure side. If the polymer is hydrophobic, it may provide the additional benefit of excluding water vapor at room temperature, e.g., at 25° C. This feature is particularly useful when the ion source material is stored in a canister sealed by the filter.

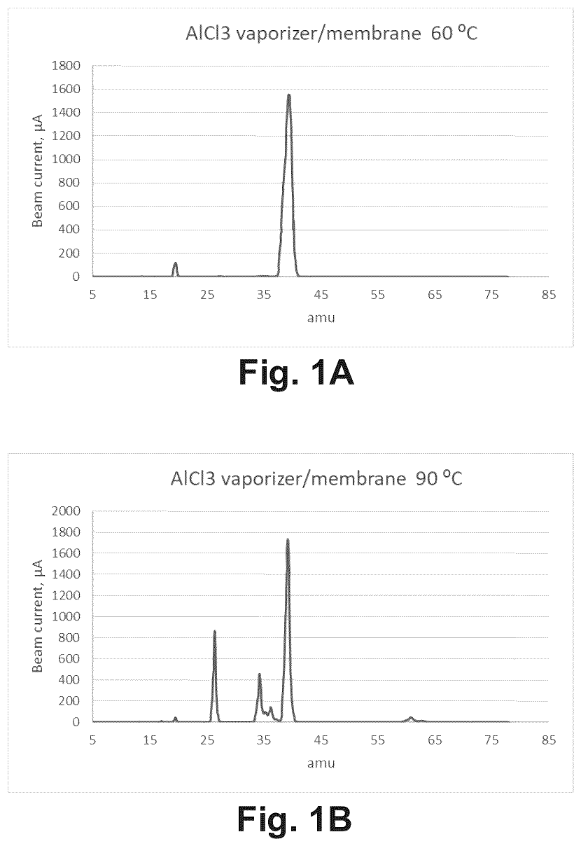

Another benefit of the membrane is that it provides a temperature-dependent impediment to the flow rate, one that increases as temperature is lowered and lessens as temperature is increased. This advantage is illustrated by the data shown FIGS. 1A and 1B, which was obtained by measuring ion beam current over a range of mass to charge ratios in an ion implantation system running an argon plasma and having aluminum chloride in a vaporizer with a Teflon™ membrane over the top of the vaporizer oven. FIG. 1A shows the results for vaporizer setpoint temperature of 60° C. FIG. 1B shows the results for vaporizer setpoint temperature of 90° C. The aluminum ions at mass 27 (and chlorine ions at masses 35 and 37) are virtually undetectable when the vaporizer setpoint temperature is 60° C. The aluminum ions are at an operational level when the vaporizer setpoint temperature is 90° C. The difference in production of aluminum ions is over two orders of magnitude, which is a far greater difference than can be explained by the increase in partial pressure of the aluminum chloride that can be caused by a 30° C. temperature increase. This temperature-dependent behavior improves control over the supply of the ion source material from the vaporizer to the arc chamber.

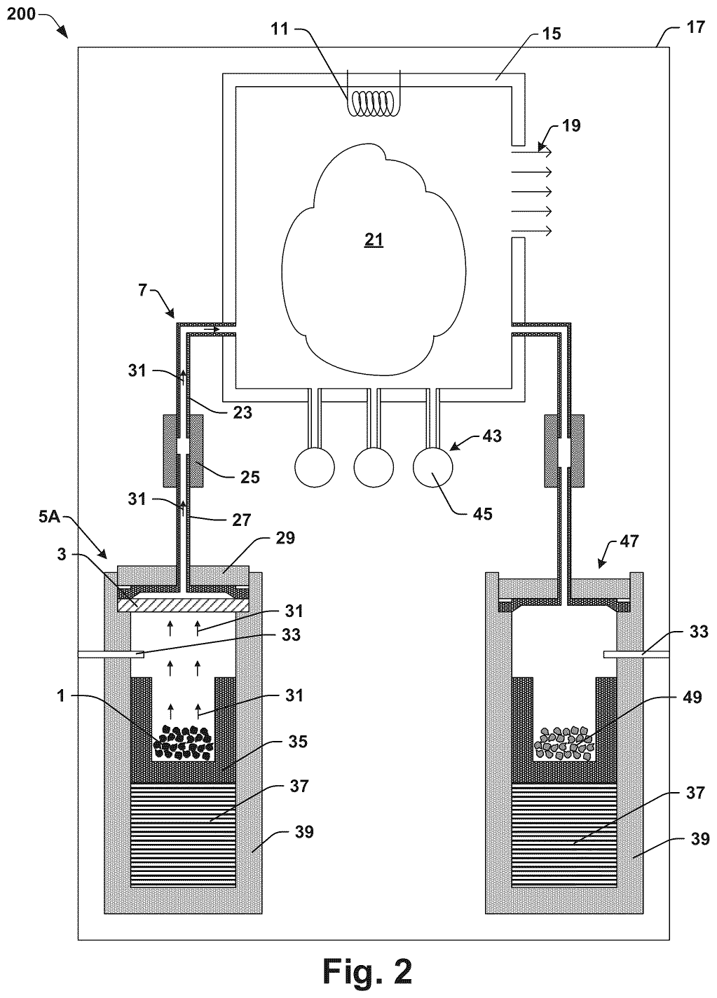

FIG. 2 illustrates a cross-sectional view 200 of an ion source 17 according to some aspects of the present disclosure. The ion source 17 includes a vaporizer 5A fluidly coupled to an arc chamber 15 by a passage 7. The vaporizer 5A includes an oven 39, a heater 37, a thermocouple 33, and a crucible 35. The passage 7 may include a tube 23 and a nozzle 27 coupled through a sleeve 25. A filter 3 is positioned to impede a flow of a vapor from the ion source material 1 to the arc chamber 15.

In operation, an ion source material 1 is placed in the oven 39 within the crucible 35. The filter 3 may then be placed over the oven 39 and clamped to the top of the oven 39 along with the nozzle 27 by the clamping member 29. The clamping member 29 may be biased against the top of the oven 39 by a spring (not shown) or otherwise secured. The nozzle 27 may then be slid into the sleeve 25 to complete the passage 7.

When there is a demand for ions 19 of the type provided by the ion source material 1, the heater 37 is operated in a feedback control loop to heat the oven 39 and cause a temperature measured by the thermocouple 33 to approach a predetermined setpoint. The thermocouple 33 is shown inside the oven 39, but this is not a requirement. The thermocouple 33 can measure any temperature that tracks a temperature of the oven 39 and the feedback control system will work to provide reproducible results. The setpoint temperature may vary in relation to the actual location of the thermocouple 33.

Once the oven 39 has warmed, the ion source material 1 begins to produce a vapor 31. In some embodiments, the ion source material 1 produces the vapor 31 by sublimation. The vapor 31 flows (by diffusion or otherwise) through the filter 3, through the passage 7, and into the arc chamber 15. Within the arc chamber 15, electrons are generated from an electron source such as a filament or cathode 11. The filament or cathode 11 is heated with a current to induce thermionic emission of electrons. The electrons are induced to arc so as to ionize the vapor 31 and other gases in the arc chamber 15 and produce a plasma 21. A magnetic field may be provided to contain the electrons in a spiral, which increases their travel time and thus their likelihood of ionizing gas molecules. Ions 19 may be controllably extracted from the plasma 21 and used to form an ion beam.

The flow rate of the vapor 31 to the arc chamber 15 may be mass transport rate limited, as opposed to being limited by the rate of heating of the ion source material 1. The design of the passage 7 is such so as to make this true even without the filter 3. When the flow rate is mass transport rate limited, the partial pressure of the vapor 31 in the oven 39 approaches the equilibrium partial pressure for the ion source material 1 at the oven temperature. It may be assumed that the partial pressure in the oven 39 is within about 50% of the equilibrium partial pressure and may be much closer to the equilibrium partial pressure. The flow rate of the vapor 31 to the arc chamber 15 is then proportional to a partial pressure difference between the vapor 31 in the oven 39 and the vapor 31 in the arc chamber 15. The proportionality factor may be referred to as a mass transfer coefficient.

In terms of the mass transfer coefficient, the various resistances to flow may be treated as resistances in series. The main resistances are the filter 3 and the passage 7. The resistance of the filter 3 is greater than the resistance of the passage 7 combined with all other resistances in the path from the ion source material 1 to the arc chamber 15. Accordingly, a pressure drop of the vapor 31 across the filter 3 is greater than half the pressure drop of the vapor 31 between the ion source material 1 and the arc chamber 15. The impendence to flow presented by the filter 3 is such so as to increase by at least about 20° C. the setpoint temperature. The increase in temperature is such that the vapor pressure of the ion source material 1 at least doubled.

The setpoint temperature provides a flow rate for the vapor 31 that is suitable for an ion implantation system. In some embodiments, the setpoint temperature is selected to provide a flow rate in the range from about 1,000 μg/min to about 100,000 μg/min. In some embodiments, the setpoint temperature is selected to provide a flow rate in the range from about 3,000 μg/min to about 30,000 μg/min. The setpoint temperature is selected to provide the desired flow rate. The flow rate is the product of the mass transport coefficient and the pressure differential. The pressure differential is a function of the setpoint temperature and is mostly determined by the vapor pressure of the ion source material 1 at the oven temperature. The partial pressure of the ion source material 1 in the arc chamber 15 is generally an order of magnitude (or more) less than the partial pressure of the ion source material 1 in the vaporizer 31. The pressure of the ion source material 1 in the arc chamber 15 is generally less than 100 mTorr and is commonly less than 10 mTorr. The vapor pressure increases of the ion source material in the oven increases with temperature. The mass transfer coefficient may also increase with temperature.

The term “filter” is used herein in the sense of a structure that provides impedance to flow. Different species and different material phases will tend to have different flow rates through a filter and this effect may be used to provide separation, but the function targeted by the usage of a filter in the present application is impedance to flow of the desired species. A filter designed for separation is designed to provide minimal resistance to flow of the desired species. A filter designed for the present application is designed to provide a target level of resistance to flow of the desired species.

It will be appreciated that in addition to a filter, any flow attenuating device may be used to impede the flow and raise the setpoint temperature. A flow attenuator could be a physical structure that inhibits flow such as an orifice or the like. In some embodiments, the flow attenuator is a capillary tube bundle. A capillary tube bundle may provide a more uniform flow restriction and may be less prone to clogging than an orifice.

In some embodiments, the filter 3 comprises a porous structure. A porous structure may be a bed of particles. In some embodiments, the porous structure is a frit. A frit is a structure produced by causing a mass of particles to adhere to one another. A frit has the advantage of being easy to handle. The particles may be a metal such aluminum, stainless steel, or the like, glass, a refractory material, or any other suitable material. The particles may be heated and fused together, with or without applying pressure.

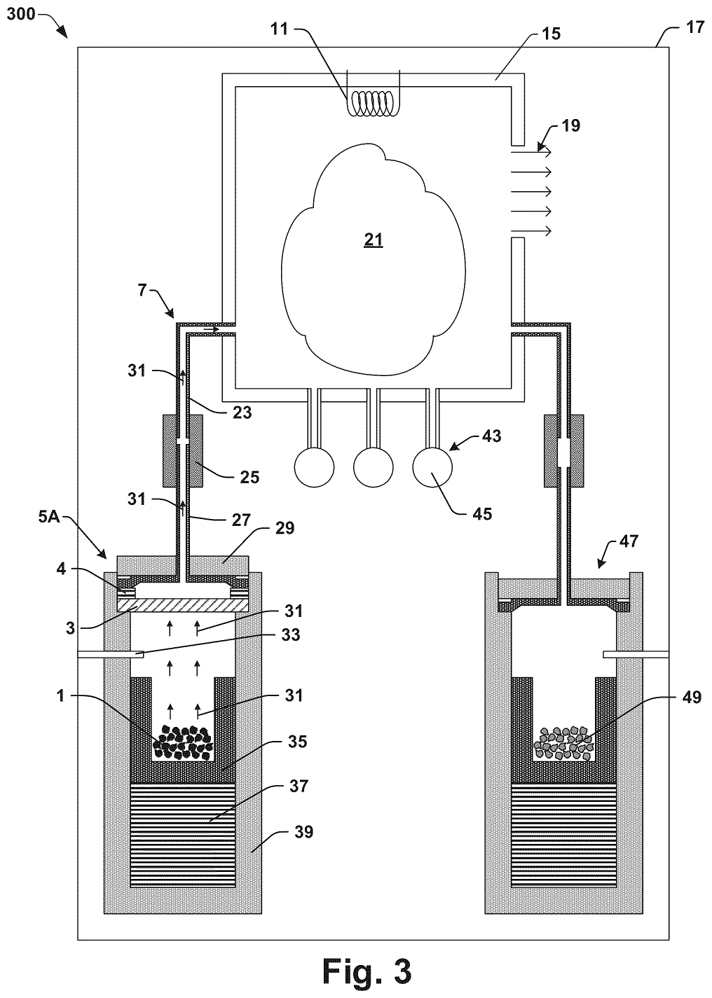

A difficulty with using a frit or other porous structure is that the vapor may deposit on the frit, reducing its porosity. This is particularly a concern if the frit temperature is allowed to fall below the temperature of the ion source material 1. A solution to this problem is to provide a second heater next to the frit. FIG. 3 provides an illustration 300 of the ion source 17 modified so that a heater 4 is located next to the frit. With such a heater 4, deposition of the ion source material 1 can be advantageously used. When the vaporizer 5A shuts down, the filter 3 may be allowed to cool faster than the ion source 1 so that vapor 31 deposits on the filter 3, reducing its porosity. The reduced porosity protects the ion source material 1 from contaminants and increases the protection of the arc chamber 15 from unintentionally vaporized ion source material 1. The filter 3 may be reheated and the deposits evaporated when the vaporizer 5A is brought back online.

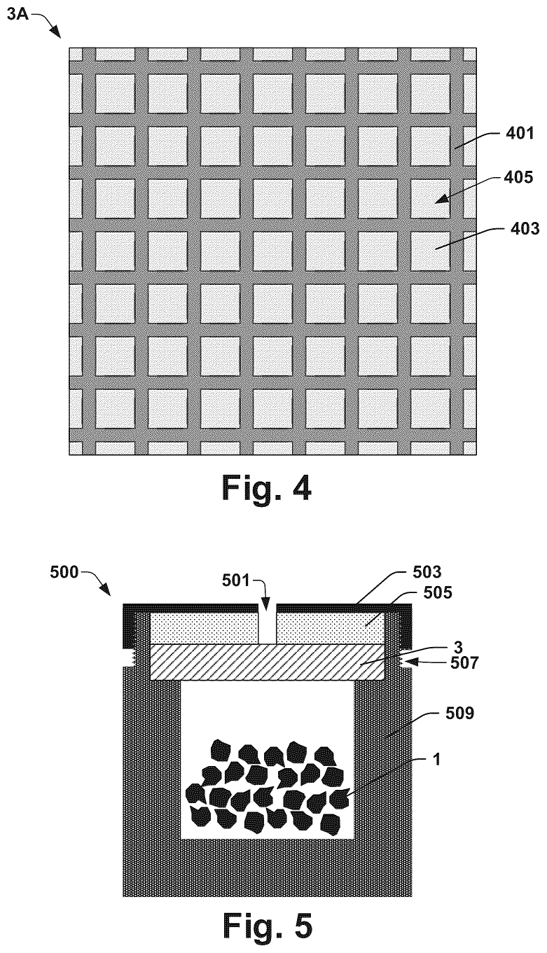

In some embodiments, the filter 3 comprises a membrane. The membrane may be supported by a mesh. FIG. 4 illustrates a filter 3A that provides an example. As shown in FIG. 4, the filter 3A include a mesh 401 and a membrane 403 that extends over the mesh 401 and across the mesh openings 405 to form a sheet. The mesh 401 may be any suitable material. In some embodiments, the mesh 401 is metal. A suitable metal may be stainless steel, aluminum, or the like. In some embodiments, the mesh openings 405 may have widths in the range from about 10 microns to about 100 microns. For example, the mesh 401 may be a 37 micron stainless steel mesh or the like.

The membrane 403 may be non-porous. In some embodiments, the membrane 403 is a material capable of absorbing the ion source material 1 (see FIG. 2). The source material 1 passes through the membrane 403 by absorbing on the high pressure side of the membrane 403, diffusing through the membrane 403, and desorbing on the low pressure side of the membrane 403. The absorption coefficient or solubility of the ion source material 1 increases with increasing temperature. Accordingly, the permeability of the membrane 403 is temperature dependent with respect to the ion source material 1. This temperature dependent behavior combines with the temperature dependence of the vapor pressure to provide a sharp variation of the flow rate of the vapor 31 with temperature. This allows the vaporizer 5A to have a narrowly-defined temperature range above which a flow of the vapor 31 is provided and below which the flow is essentially stopped. The temperature range may be controlled by selecting the composition of the membrane 403. In some embodiments, the membrane 403 is a polymer membrane. In some embodiments, the polymer is hydrophobic. In some embodiments, the polymer is Teflon™. For example, the membrane 403 may be Teflon™ AF 2400 or the like. Aluminum salts including aluminum chloride (AlCl₃) and aluminum iodide (AlI₃) are soluble in Teflon™ membranes. Water (H₂O) and oxygen (O₂), on the other hand, are not significantly soluble in Teflon™ membranes at room temperature, e.g., 25° C.

Returning to FIG. 2, the ion source 17 may include a second vaporizer 47 and a plurality of gas sources 43. Fluid communication between the gas sources 43 and the arc chamber 15 is selectively controlled by valves 45. The second vaporizer 47 may be in unregulated fluid communication with the arc chamber 15 and may have substantially the same structure as the vaporizer 5A and may be controlled in the same manner as the vaporizer 5A, but the second vaporizer 47 does not have the filter 3 or any counterpart. A second ion source 49 having a lower vapor pressure than the ion source 1 is in the second vaporizer 47. When using the second ion source 49, it is preferable not to have the filter 3 impeding the flow to the arc chamber 15. Some ion sources already need oven temperatures of 200° C. or more, 400° C. or more, or even higher, and driving up the operating temperature with a filter 3 would be undesirable.

FIG. 5 illustrates a canister 500 in accordance with some embodiments. The canister 500 includes a container body 509 and a lid 503. The lid 503 and the container body 509 may have threads 507 so that the lid 503 can be screwed onto the container body 509. The filter 3 may be clamped between the lid 503 and the container body 509. A gasket 505 may be employed between the filter 3 and the lid 503. In some embodiments, the lid 503 has an orifice 501 that is much smaller than the filter 3 (e.g., less than 10% of the area). Keeping the orifice 501 narrow facilitates containment and isolation of the ion source material 1 that is in the container body 509. The canister 500 is suitable for shipping and storing the ion source material 1. In some embodiments, the gasket 505 is porous with a porosity greater than that of the filter 3. This porosity allows the gasket 505 to cover a large area of the filter 3 without blocking the filter 3.

The ion source material 1 is a precursor for an ion that may be implanted by an ion implantation system. In some embodiments, the precursor comprises an N-type dopant or a P-type dopant. Examples of N-type dopants include phosphorous (P), arsenic (As), antimony (Sb), tin (Sn), and the like. Examples of P-type dopants include aluminum (Al), boron (B), gallium (Ga), indium (In) and the like. In some embodiments, the ion source material has a sublimation temperature less than or equal to the of aluminum iodide (AlI₃). In some embodiments, the ion source material is an aluminum salt, a gallium salt, and indium salt, or a tin salt. These salts are particularly susceptible to unintended vaporization.

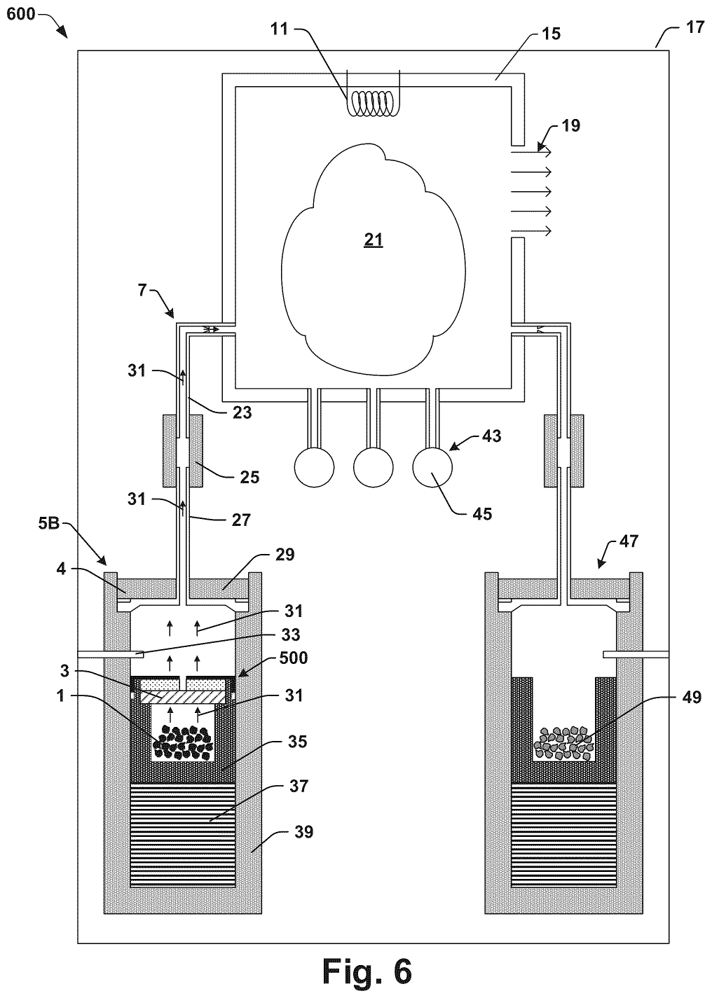

FIG. 6 provides a cross-sectional view 600 of the ion source 17 with a vaporizer 5B. The vaporizer 5B is like the vaporizer 5A of FIG. 2 except that in the vaporizer 5B, the canister 500 replaces the crucible 35 and the filter 3 is in the oven 39 at the top of the container body 509 rather than at the top of the oven 39. The canister body may have dimensions and a composition similar to that of the crucible 35. In particular, the container body 509 may be a metal, graphite, or some other material that is chemically inert and able to withstand high temperatures. A suitable metal may be, for example, stainless steel, aluminum, tantalum or the like. In some embodiments, the container body 509 is graphite or the like. Graphite is particularly desirable in that some ion implantation systems are sensitive to contamination from metal ions.

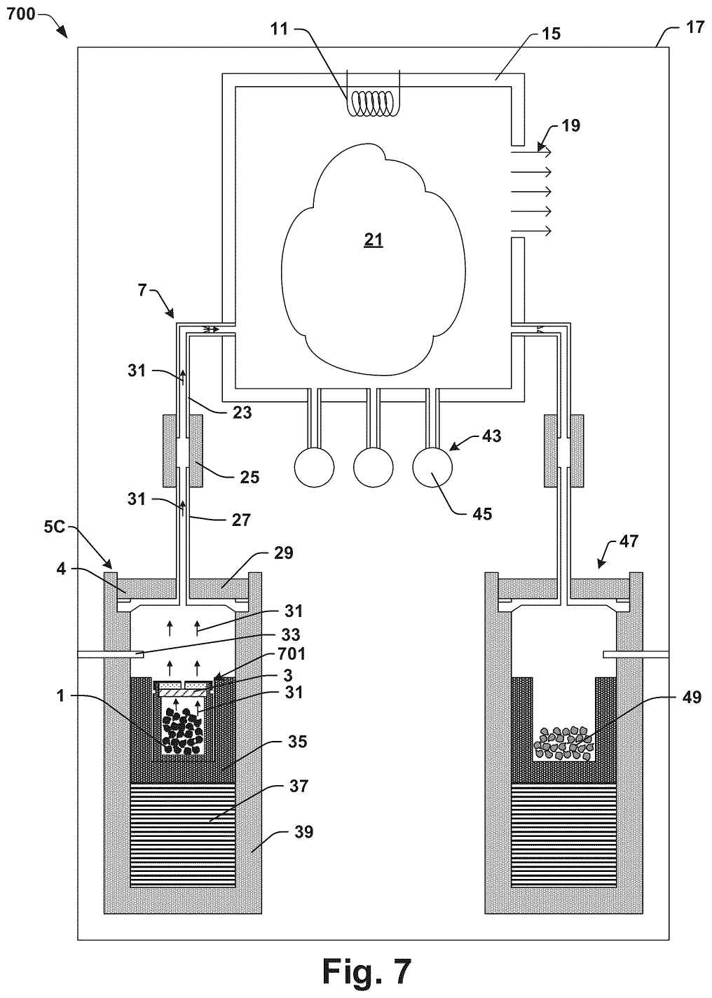

FIG. 7 provides a cross-sectional view 700 of the ion source 17 with a vaporizer 5C. The vaporizer 5C is like the vaporizer 5B of FIG. 6 except that it holds the canister 701. The canister 701 may be like the canister 500 of FIGS. 5 and 6 except that it is smaller so that it fits within the crucible 35. The canister 701 that fits inside the crucible 35 may have the advantage of being easier to use. The canister 500 that replaces the crucible 35 has the advantage of a greater holding capacity than the canister 701.

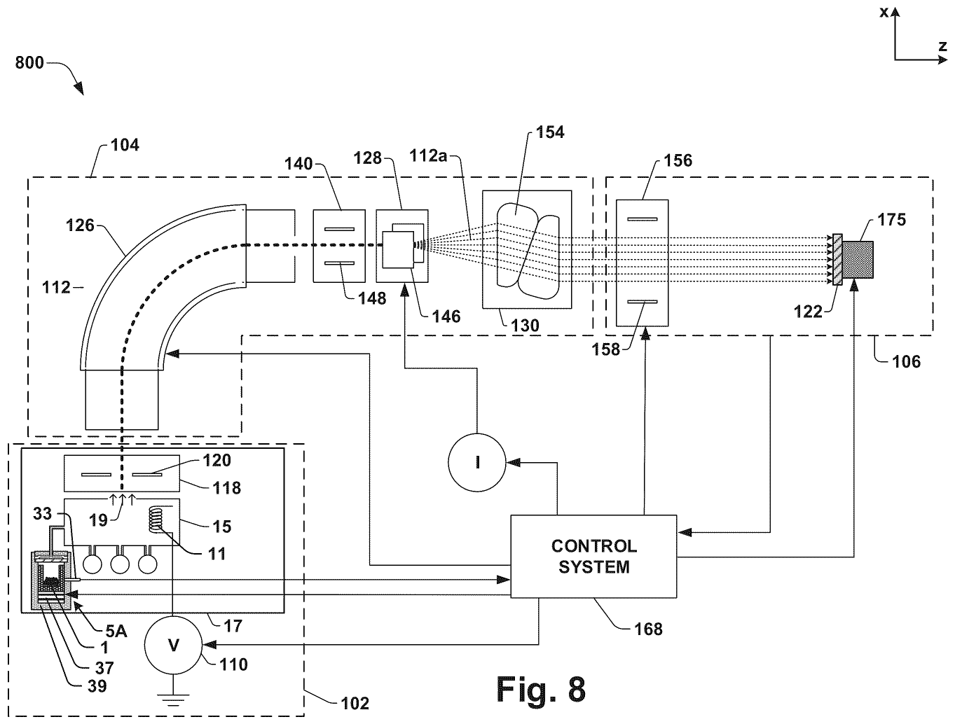

FIG. 8 illustrates an exemplary ion implantation system 800 that includes a terminal 102, a beamline 104, and an end station 106. The terminal 102 includes the ion source 17, which is powered by a high voltage power supply 110 so as to produces the ions 19. The ions 19 are formed into an ion beam 112 that is filtered, shaped, and steered by the beamline 104. The end station 106 receives the ion beam 112 where it may be used to implant a workpiece 122 handled by a workpiece support 175.

The ions 19 are extracted and formed into the ion beam 112 by an ion extraction assembly 118. The ion extraction assembly 118 may include electrodes 120 that accelerate the extracted ions. The beamline 104 may include a mass analyzer 126, a beam shaping and steering system 140, a scanning system 128, and a parallelizer 130. The mass analyzer 126 filters the ions based on charge-to-mass ratio so that after the mass analyzer 126 the ion beam 112 is a purified ion beam that includes only select ions. In the illustrated example, the mass analyzer 126 includes a bend through which the ions are deflected by a magnetic field. Ions having the wrong charge-to-mass ratio will be over-deflected or under-deflected so that only the ions having the desired charge-to-mass ratio continue down the beamline 104 from the mass analyzer 126.

The beam shaping and steering system 140 includes one or more electrical or magnetic lenses 148 that compresses and steer the ion beam 112. The beam shaping and steering system 140 may include a first quadrupole magnet that squeezes the ion beam 112 in the x-direction (an x-quad) and a second quadrupole magnet that squeezes the ion beam 112 in the y-direction (a y-quad). The y-direction is into the page of FIG. 8. Other options for compressing and steering the ion beam 112 include electrostatic systems, other magnetic systems, and combinations thereof.

The scanning system 128 steers the ion beam 112 so that the beam path 112a sweeps across the x-direction. The scanning system 128 may include plates 146. The plates 146 may steer the ion beam 112 either electrically or magnetically. The scanned ion beam 112 may be passed through a parallelizer 130. In the illustrated example, the parallelizer 130 includes two dipole magnets 154. The two dipole magnets 154 may be substantially trapezoidal and oriented to mirror one another and bend the beam paths 112a into s-shapes. The parallelizer 130 has the effect of making all the beam paths 112a substantially parallel.

A deceleration stage 156 may be provided and located within the end station 106. The deceleration stage 156 includes one or more electrodes 158 that slow the ion beam 112 and focus the ion beam 112 into a converging stream. The deceleration stage 156 may include, for example, an Einzel lens.

A control system 168 (also called a controller) may be provided to control, communicate with, and/or adjust the high voltage power supply 110, the heater 37, the thermocouple 33, the mass analyzer 126, the scanning system 128, the deceleration stage 156, and the workpiece support 175. The control system 168 may comprise a computer including a central processing unit and a memory system programmed with instructions for operating these and other components of the ion implantation system 800. For example, the control system 168 may determine the amount of power provided by the high voltage power supply 110, the amount of heat generated by the heater 37, and other parameters that affect the rate at which ions 19 are produced in the ion source 17. The control system 168 may also control a beamline energy, a fast scan rate, a slow scan rate, and an amount of deceleration of the ion beam 112 (if any).

The control system 168 may receive a set of operating parameters constituting a recipe through which an operator may direct the ion implantation system 800 to conduct a specific and reproducible ion implantation operation. In implementing those instructions, the control system 168 may apply one or more feedback control loops. One control loop may regulate a temperature of the oven 39 by operating the heater 37 according to feedback from the thermocouple 33. Another control loop may implement autotune, by which is meant operating the high voltage power supply 110 using feedback relating to beam current, which feedback may be provided by the end station 106.

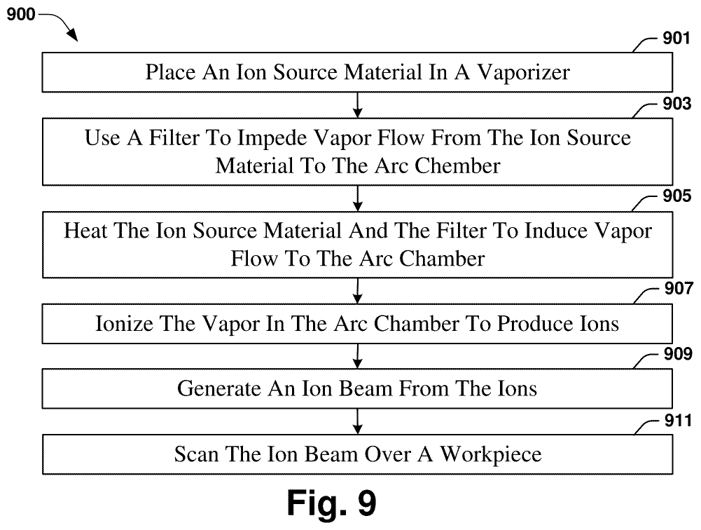

FIG. 9 provides a flow chart for a method 900 of operating an ion implantation system in accordance with some aspects of the present disclosure. The method 900 begins with act 901, placing an ion source material in the oven of a vaporizer. Optionally, the ion source material is placed inside a canister and the canister is placed inside the oven. The vaporizer may then be placed inside the ion source of an ion implantation system, or the vaporizer may already be inside the ion source.

Act 903 is using a filter to impede a vapor of the ion source material from flowing from the ion source material to the arc chamber of the ion implantation system. The filter may be inside the oven with the ion source material, between the oven and a passage that leads to the arc chamber, or in a passage that leads from the vaporizer to the arc chamber. The filter may be put in position before the ion source material is placed in the oven, after the ion source material is placed in the oven, or simultaneously with placing the ion source material in the oven. For example, the filter may be attached to a canister that holds the ion source material and the canister with the ion source material and filter may be placed in the oven.

Act 905 is heating the ion source material and the filter to induce a vapor of the ion source material to flow to the arc chamber. In some embodiments, the vapor flow to the arc chamber will not be sufficient if the filter is not heated. In some embodiments, the filter is heated together with the ion source material as in the case where the filter is inside the over together with the ion source material. In some embodiments, the filter is heated indirectly by the oven. In some embodiments, a separate heat source is applied to the filter to induce permeability of the filter. In the latter case, the filter may be heated before the ion source material.

Act 907 is ionizing the vapor in the arc chamber to produce ions of the ion source material. It may be that only a fraction of the vapor is converted to ions with the rest being removed by a vacuum pump. Act 909 is generating an ion beam from ions extracted from the arc chamber. Act 911 is scanning the ion beam over a workpiece.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. In addition, while a particular feature may have been disclosed with respect to only one of several embodiments, such feature may be combined with one or more other features of the other embodiments as may be desired or advantageous for a given application.

What is claimed is:

1. An ion implantation system, comprising:
an arc chamber;
a vaporizer comprising an oven and a first heater, wherein the first heater is configured to heat the oven, and the vaporizer is fluidly coupled to the arc chamber by a passage; and
a flow attenuator, wherein the flow attenuator is configured to impede a flow of a vapor from an area of the oven to the arc chamber.

2. The ion implantation system of claim 1, wherein the flow attenuator is a filter.

3. The ion implantation system of claim 2, wherein the filter provides a temperature-dependent impediment to the flow of the vapor.

4. The ion implantation system of claim 2, wherein the filter comprises a non-porous membrane.

5. The ion implantation system of claim 4, further comprising an ion source material in the vaporizer, wherein the ion source material absorbs into the non-porous membrane at a temperature.

6. The ion implantation system of claim 2, wherein the filter comprises a mesh coated with a polymer and the polymer forms a membrane.

7. The ion implantation system of claim 2, wherein the filter comprises a polymer membrane and the polymer membrane is hydrophobic.

8. The ion implantation system of claim 2, wherein the filter is configured to prevent the passage of water vapor at room temperature.

9. The ion implantation system of claim 2, wherein the filter comprises a porous structure.

10. The ion implantation system of claim 2, wherein the filter comprises a frit.

11. The ion implantation system of claim 10, further comprising an ion source material in the vaporizer, wherein the ion source material deposits in the frit so as to reduce a porosity of the frit when a temperature of the oven is lowered from a first temperature to a second temperature.

12. The ion implantation system of claim 2, wherein the filter is attached to a container within the oven.

13. The ion implantation system of claim 12, wherein the container is in a crucible that is in the oven.

14. The ion implantation system of claim 2, wherein:
the vaporizer comprises a body and a cap; and
the filter is clamped between the body and the cap.

15. The ion implantation system of claim 1, further comprising a second heater, wherein the second heater is configured to directly heat the flow attenuator.

16. The ion implantation system of claim 2, further comprising an ion source, wherein the arc chamber and the vaporizer are within the ion source.

17. A canister, comprising:
a container body;
an ion source material in the container body, wherein the ion source material comprises an N-type or P-type dopant; and
a filter, wherein the container body is enclosed by the filter and the filter is configured to provide a temperature-dependent impediment to passage of a vapor of the ion source material.

18. The canister of claim 17, wherein the ion source material is an aluminum salt, a gallium salt, an indium salt, or a tin salt.

19. A method of operating an ion implantation system, the method comprising:
placing an ion source material that is in a solid phase in a vaporizer, wherein the vaporizer is connected by a passage to an arc chamber of an ion implantation system;
using a filter to provide a barrier between the ion source material in the vaporizer and the arc chamber;
heating the ion source material in the vaporizer and heating the filter, wherein heating causes the ion source material to emit a vapor, and heating the filter increases a permeability of the filter with respect to the vapor;
allowing the vapor to diffuse through the filter and migrate to the arc chamber;
ionizing a portion of the vapor in the arc chamber to generate ions; and
forming an ion beam from the ions.

20. The method of claim 19, wherein the filter increases by at least 20° C. a setpoint temperature at which the ion source material is supplied from the vaporizer to the arc chamber at a given rate.
